(19) United States
(12) Patent Application Publication
(10) Pub. No.: US 2026/0033179 A1
(43) Pub. Date: Jan. 29, 2026

(54) DISPLAY SUBSTRATE AND DISPLAY PANEL

(71) Applicants: Chengdu BOE Optoelectronics Technology Co., Ltd., Chengdu, Sichuan (CN); BOE Technology Group Co., Ltd., Beijing (CN)

(72) Inventors: Xuewei TIAN, Beijing (CN); Yipeng CHEN, Beijing (CN)

(21) Appl. No.: 18/996,016

(22) PCT Filed: Apr. 17, 2024
(86) PCT No.: PCT/CN2024/088225

§ 371 Date: Jan. 17, 2025

(30) Foreign Application Priority Data
May 30, 2023 (CN) 202310627205.1

(51) Int. Cl. H10K 59/131; H10K 59/40

(52) U.S. Cl. CPC H10K 59/131; H10K 59/40

(57) ABSTRACT

A display substrate has a display area and a bezel area, includes: a base substrate in the display area and the bezel area; multiple pixel circuits located in the display area; multiple light-emitting elements on a side of the pixel circuits away from the base substrate and in the display area, the pixel circuits drives the light-emitting elements to emit light, at least one of the light-emitting elements including a first electrode, a light-emitting layer, and a second electrode sequentially disposed away from the base substrate; a first signal line in the bezel area and electrically connected with the second electrode; multiple second signal lines connected to a functional element, at least part of the second signal lines being located in the bezel area, orthographic projections of each of the at least part of the second signal lines and the first signal line on the base substrate are overlapped.

### TECHNICAL FIELD

The present disclosure relates to the field of display technology, and particularly relates to a display substrate and a display panel.

### BACKGROUND

In recent years, the development of full screen displays has been very rapid, which has put forward new requirements for the form of screens. As display screens move towards the era of full screen displays, products with narrow bezels have been increasingly attracting people's attention for increasing screen to body ratio.

### SUMMARY

In a first aspect, an embodiment of the present disclosure provides a display substrate including a display area and a bezel area, the bezel area at least partially surrounding the display area, where the display substrate includes:
a base substrate located in the display area and the bezel area;
a plurality of pixel circuits located on a side of the base substrate and located in the display area;
a plurality of light-emitting elements located on a side of the plurality of pixel circuits away from the base substrate and located in the display area, the plurality of pixel circuits being configured to drive the plurality of light-emitting elements to emit light, at least one of the plurality of light-emitting elements including a first electrode, a light-emitting layer, and a second electrode sequentially disposed away from the base substrate;
a first signal line located in the bezel area and is electrically connected with the second electrode; and
a plurality of second signal lines located on a side of the base substrate and configured to be connected to a functional element, where at least part of the second signal lines are located in the bezel area, and an orthographic projection of each of the at least part of the second signal lines on the base substrate is overlapped with an orthographic projection of the first signal line on the base substrate.

In some implementations, an orthographic projection of each of the plurality of second signal lines on the base substrate is overlapped with the orthographic projection of the first signal line on the base substrate.

In some implementations, an orthographic projection of each of the plurality of second signal lines on the base substrate is located within the orthographic projection of the first signal line on the base substrate.

In some implementations, the first signal line includes at least two conductive layers located in different layers and electrically connected with each other, the at least two conductive layers including a first conductive layer and a second conductive layer.

In some implementations, one of the first conductive layer and the second conductive layer is in the same layer as the at least part of the second signal lines, and an orthographic projection of the other of the first conductive layer and the second conductive layer on the base substrate is overlapped with the orthographic projection of each of the at least part of the second signal lines on the base substrate.

In some implementations, the second conductive layer is located on a side of the first conductive layer away from the base substrate, the first conductive layer is located in the same layer as the at least part of the second signal lines, and an orthographic projection of the second conductive layer on the base substrate is overlapped with the orthographic projection of each of the at least part of the second signal lines on the base substrate.

In some implementations, the second conductive layer is located on a side of the first conductive layer away from the base substrate, the second conductive layer is located in the same layer as the at least part of the second signal lines, and an orthographic projection of the first conductive layer on the base substrate is overlapped with the orthographic projection of each of the at least part of the second signal lines on the base substrate.

In some implementations, the first signal line further includes a third conductive layer located on a side of the first conductive layer and the second conductive layer away from the base substrate, the first conductive layer, the second conductive layer, and the third conductive layer being electrically connected together.

In some implementations, an orthographic projection of the third conductive layer on the base substrate is overlapped with the orthographic projection of each of the at least part of the second signal lines on the base substrate.

In some implementations, the first signal line further includes a fourth conductive layer located on a side of the first conductive layer and the second conductive layer close to the base substrate,
the fourth conductive layer, the first conductive layer and the second conductive layer being sequentially stacked away from the base substrate, and
an orthographic projection of the fourth conductive layer on the base substrate being overlapped with the orthographic projection of each of the at least part of the second signal lines on the base substrate.

In some implementations, the first signal line further includes a fourth conductive layer and a fifth conductive layer located on a side of the first conductive layer and the second conductive layer close to the base substrate, and a third conductive layer and a sixth conductive layer located on a side of the first conductive layer and the second conductive layer away from the base substrate, and where
the fifth conductive layer, the fourth conductive layer, the first conductive layer, the second conductive layer, the third conductive layer, and the sixth conductive layer are sequentially stacked away from the base substrate,
the first conductive layer, the second conductive layer, the third conductive layer, the fourth conductive layer, the fifth conductive layer, and the sixth conductive layer are electrically connected together, the at least part of the second signal lines are located in the same layer as the fourth conductive layer, and orthographic projections of the fifth conductive layer and the sixth conductive layer on the base substrate are each overlapped with the orthographic projection of each of the at least part of the second signal lines on the base substrate.

In some implementations, the touch panel further includes: a first connection electrode, a second connection electrode, and at least one touch electrode layer located on a side of the pixel circuits away from the base substrate; and a shielding layer located on a side of the pixel circuits close to the base substrate, where
each pixel circuit includes at least one thin film transistor, each thin film transistor including an active layer located on a side of the base substrate, a gate electrode located on a side of the active layer away from the base substrate, and a source electrode and a drain electrode located on a side of the gate electrode away from the base substrate;
an orthographic projection of the shielding layer on the base substrate is overlapped with an orthographic projection of the active layer on the base substrate;
the first connection electrode is located on a side of the thin film transistor away from the base substrate, and is electrically connected with the thin film transistor;
the second connection electrode is located on a side of the first connection electrode away from the base substrate, and is electrically connected with the first connection electrode;
the light-emitting element is located on a side of the second connection electrode away from the base substrate, and is electrically connected with the second connection electrode;
the at least one touch electrode layer is located on a side of the light-emitting element away from the base substrate;
the first conductive layer and the first connection electrode are located in a same layer;
the second conductive layer and the second connection electrode are located in a same layer;
the third conductive layer and the first electrode are located in a same layer;
the fourth conductive layer is located in the same layer as the source electrode and the drain electrode;
the fifth conductive layer and the shielding layer are located in a same layer; and
the sixth conductive layer and any one of the at least one touch electrode layer are located in a same layer.

In some implementations, the bezel area includes a first bezel area, a second bezel area, a third bezel area, and a fourth bezel area sequentially disposed around the display area, the functional element is located in the display area, and the functional element is disposed close to the first bezel area,
the functional part is respectively connected with the second signal lines through signal leads, and the signal leads extend from the functional element to the first bezel area and are connected with the second signal lines in the first bezel area;
the display substrate further includes signal input pads located in the third bezel area, where
the plurality of second signal lines extend from the first bezel area to the third bezel area through the second bezel area and are connected with the signal input pads.

In some implementations, the first signal line is located in at least the first bezel area, the second bezel area, and the fourth bezel area, and the orthographic projection of each of the at least part of the second signal lines on the base substrate is overlapped with an orthographic projection of a part of the first signal line in the second bezel area on the base substrate.

In a second aspect, an embodiment of the present disclosure provides a display substrate including a display area and a bezel area, the bezel area at least partially surrounding the display area, and the display substrate includes a base substrate, a plurality of pixel units, a functional element, a first signal line and a second signal line, where
the pixel units, the functional element, the first signal line and the second signal line are respectively located on a side of the base substrate;
the pixel unit includes a pixel circuit and a light-emitting element, the light-emitting element being located on a side of the pixel circuit away from the base substrate, and the pixel circuit being electrically connected with the light-emitting element;
the pixel unit and the functional element are located in the display area, and the pixel unit at least partially surrounds the functional element;
the first signal line and the second signal line are located in the bezel area;
the first signal line is electrically connected with the pixel unit, and the second signal line is electrically connected with the functional element;
the first signal line includes at least two conductive layers, the at least two conductive layers are located in different layers, an insulating layer is arranged between any two adjacent ones of the at least two conductive layers, and any two adjacent ones of the at least two conductive layers are connected with each other through a via hole formed in the insulating layer; and
the second signal line and one of the at least two conductive layers are located in a same layer, and an orthographic projection of the second signal line on the base substrate is overlapped with an orthographic projection of at least one of the at least two conductive layers on the base substrate.

In some implementations, the first signal line includes at least three conductive layers, every two adjacent ones of the at least three conductive layers form a group, the at least three conductive layers include at least two groups, and
the orthographic projection of the second signal line on the base substrate is overlapped with the orthographic projection of a connection via hole between two adjacent conductive layers of each of at least one group in at least two groups on the base substrate.

In some implementations, at least two conductive layers of the at least three conductive layers are located on a side of the second signal line away from the base substrate, and any two adjacent ones of the at least two conductive layers are connected with each other through a first via hole formed in the insulating layer; and
the orthographic projection of the second signal line on the base substrate is located within an orthographic projection of the first via hole on the base substrate.

In some implementations, a conductive layer located in the same layer as the second signal line is connected with a conductive layer adjacent to the second signal line and located on the side of the second signal line away from the base substrate through a second via hole provided in the insulating layer, and
an orthographic projection of the second via hole on the base substrate is located within the orthographic projection of the first via hole on the base substrate.

In some implementations, at least one of the at least three conductive layers is located on a side of the second signal line close to the base substrate,
the conductive layer in the same layer as the second signal line is connected with the conductive layer which is located on the side of the second signal line close to the base substrate and is adjacent to the second signal line through a third via hole formed in the insulating layer, and
an orthographic projection of the third via hole on the base substrate is located within the orthographic projection of the first via hole on the base substrate.

In some implementations, a plurality of second signal lines are provided, and the plurality of second signal lines are distributed at intervals;
a total distribution width of orthographic projections of the second signal lines on the base substrate is larger than a width of the orthographic projection of the second via hole on the base substrate, and
the total distribution width of the orthographic projections of the second signal lines on the base substrate is larger than a width of the orthographic projection of the third via hole on the base substrate.

In some implementations, at least two conductive layers of the at least three conductive layers are located on a side of the second signal line close to the base substrate, and any two adjacent ones of the at least two conductive layers are connected together through a fourth via hole formed in the insulating layer; and
the orthographic projection of the second signal line on the base substrate is overlapped with an orthographic projection of the fourth via hole on the base substrate.

In some implementations, at least one of the at least three conductive layers is located on a side of the second signal line away from the base substrate, and
the orthographic projections of the fourth via hole and the second signal line on the base substrate are located within an orthographic projection of the conductive layer located on the side of the second signal line away from the base substrate side on the base substrate.

In some implementations, the conductive layer located in the same layer as the second signal line is connected with the conductive layer located on the side of the second signal line close to the base substrate and adjacent to the second signal line through a fifth via hole formed in the insulating layer;
the conductive layer in the same layer as the second signal line is connected with the conductive layer located on the side of the second signal line away from the base substrate and adjacent to the second signal line through a sixth via hole formed in the insulating layer; and
orthographic projections of the fifth via hole and the sixth via hole on the base substrate coincide.

In some implementations, a plurality of second signal lines are provided, and the plurality of second signal lines are arranged at intervals;
a total distribution width of orthographic projections of the second signal lines on the base substrate is larger than a width of the orthographic projection of the fifth via hole on the base substrate.

In some implementations, the orthographic projection of the second signal line on the base substrate is not overlapped with an orthographic projection of a connection via hole connecting any two adjacent ones of the at least three conductive layers on the base substrate.

In some implementations, a plurality of second signal lines are provided, and the plurality of second signal lines are arranged at intervals;
a total distribution width of orthographic projections of the second signal lines on the base substrate is larger than a width of an orthographic projection of the connection via hole connecting any two adjacent ones of the at least three conductive layers on the base substrate.

In some implementations, at least one of the at least three conductive layers is located on a side of the second signal line away from the base substrate, and at least one of the at least three conductive layers is located on a side of the second signal line close to the base substrate.

In a third aspect, an embodiment of the present disclosure further provides a display panel, which includes the display substrate described above.

### BRIEF DESCRIPTION OF DRAWINGS

The accompanying drawings are included to provide a further understanding of the embodiments of the present disclosure, and are incorporated in and constitute a part of the description, illustrate embodiments of the present disclosure and together with the description serve to explain the present disclosure and not to limit the present disclosure. The above and other features and advantages will become more apparent to those skilled in the art by describing in detail exemplary embodiments thereof with reference to the accompanying drawings, in which:

FIG. 1a is a schematic top view of a display screen in the related art.

FIG. 1b is a schematic enlarged top view of a portion P in FIG. 1a.

FIG. 1c is a schematic cross-sectional view of a structure of FIG. 1b taken along the cutting line AA′.

FIG. 2a is a schematic top view of a display substrate according to an embodiment of the present disclosure.

FIG. 2b is an enlarged schematic top view of a portion B in FIG. 2a.

FIG. 2c is a schematic cross-sectional view of the structure of FIG. 2a taken along the cutting line CC′.

FIG. 2d is a schematic top view of a display substrate according to an embodiment of the present disclosure.

FIG. 3a is a cross-sectional view of the display substrate in FIG. 2d taken along the cutting line DD′ according to an embodiment of the present disclosure.

FIG. 3b is a cross-sectional view of the display substrate in FIG. 2d taken along the cutting line DD′ according to an embodiment of the present disclosure.

FIG. 3c is a cross-sectional view of the display substrate in FIG. 2d taken along the cutting line DD′ according to another embodiment of the present disclosure.

FIG. 3d is a cross-sectional view of the display substrate in FIG. 2d taken along the cutting line DD′ according to an embodiment of the present disclosure.

FIG. 3e is cross-sectional view of the display substrate in FIG. 2d taken along the cutting line DD′ according to an embodiment of the present disclosure.

FIG. 3f is cross-sectional view of the display substrate in FIG. 2d taken along the cutting line DD′ according to an embodiment of the present disclosure.

FIG. 3g is a cross-sectional view of the display substrate in FIG. 2d taken along the cutting line DD′ according to an embodiment of the present disclosure.

### DETAIL DESCRIPTION OF EMBODIMENTS

In order to make those skilled in the art better understand the technical solutions of the embodiments of the present disclosure, the following describes a display substrate and a display panel provided in the embodiments of the present disclosure in further detail with reference to the accompanying drawings and the detailed description.

The embodiments of the present disclosure will be described more fully hereinafter with reference to the accompanying drawings, but the embodiments shown may be embodied in different forms and should not be construed as limited to the embodiments set forth herein. Rather, these embodiments are provided so that the present disclosure will be thorough and complete, and will fully convey the scope of the present disclosure to those skilled in the art.

The embodiments of the present disclosure are not limited to the embodiments shown in the drawings, but include modifications of configurations formed based on a manufacturing process. Thus, the regions illustrated in the figures have schematic properties, and the shapes of the regions shown in the figures illustrate specific shapes of the regions, but are not intended to be limiting.

At present, bezels of the display screens are gradually becoming smaller, and various functional elements such as an antenna, an NFC, a photoelectric sensor and the like are integrated in the screen by major manufacturers, and these elements require signal lines to be lead out from the bezel area of the display screen, resulting to an increase in the width of the bezel area of the display screen.

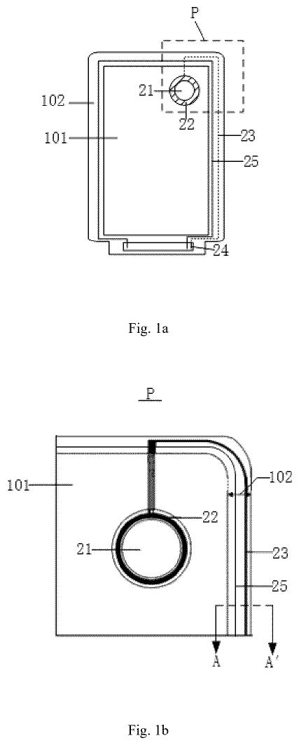

Referring to FIG. 1a, which is a schematic top view of a display screen in the related art, a camera installation hole 21 is disposed in a display area 101 of the display screen, and FIG. 1b is an enlarged schematic top view of a portion P in FIG. 1a, as shown in FIG. 1b, a circular photoelectric sensor 22 with a ring shape is accommodated in a bezel of the camera installation hole 21, and the photoelectric sensor 22 may be used to control brightness of the display screen or to control the display screen to be turned off when making or receiving a call. The photoelectric sensor 22 adopts a photodiode, a photosensitive surface of the photodiode is divided into a plurality of regions, the plurality of regions are covered by color resists with different colors, and the regions covered by the color resists with different colors are used for sensing optical signals with different colors. The photoelectric sensor 22 generally output five signals including a white signal, a red signal, a green signal, a blue signal and a black signal, and one input signal, that is, there are six signals in total, and each signal is transmitted through one signal line, so that six signal lines in total are required. Six signal lines 23 of the photoelectric sensor 22 need to be led out from the bezel area of the display screen, and finally led to a bonding terminal 24 for a peripheral circuit board located in the bezel area at a lower side of the display screen and bound and connected with the bonding terminal 24, the peripheral circuit board provides a voltage signal for the photoelectric sensor 22 through the input signal line among the six signal lines 23, and receives output voltage signals from the photoelectric sensor 22 through the five output signal lines among the six signal lines.

In order to meet the requirement for resistances of the signal lines 23, a width of each signal line 23 is required to be not less than 10 μm, a gap between two adjacent signal lines 23 is 5 μm, and the six signal lines 23 need to occupy 90 μm of the width of the bezel area.

Referring to FIG. 1c, which is a schematic cross-sectional view of the structure in FIG. 1b taken along the cutting line AA′, in the related art, the six signal lines 23 are provided on an outer side, which is away from the display area 101, of the power line (VSS) 25 of the bezel area of the display screen, and are located on an outer side of a boundary of an encapsulation layer 14 away from the display area 101, and the six signal lines 23 and a source 203 and a drain 204 of a transistor in a gate driving circuit 17 located in the bezel area 102 are arranged in a same layer, so that the width of the bezel area 102 of the display screen may be increased by 90 μm on the basis of a primary width of the bezel area, which is not favorable for realizing a narrow bezel of the display screen.

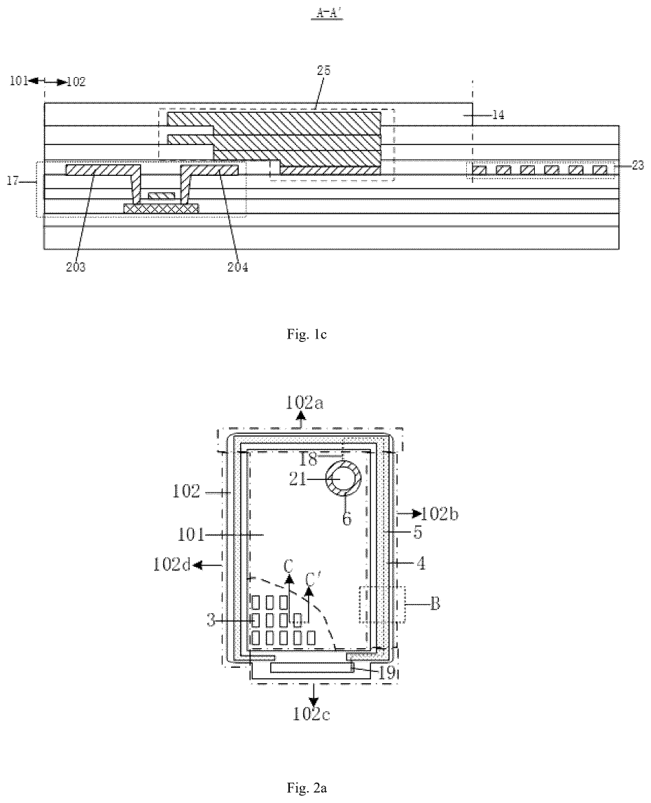

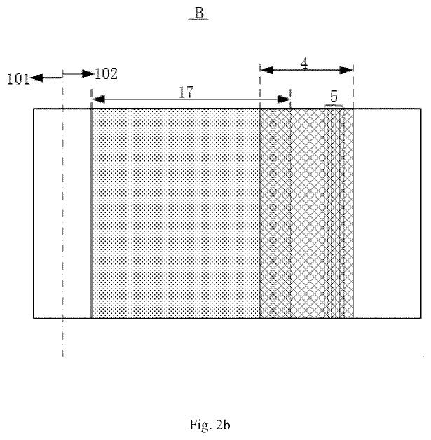

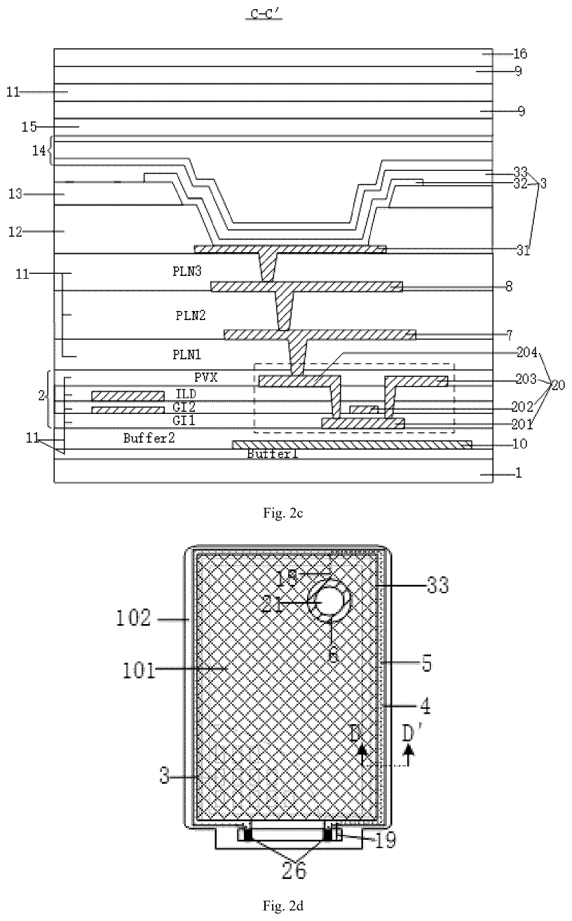

In order to solve the above problems in the related art, in a first aspect, an embodiment of the present disclosure provides a display substrate, referring to FIG. 2a, FIG. 2b, FIG. 2c, and FIG. 2d, where FIG. 2a is a schematic top view of the display substrate provided in the embodiment of the present disclosure; FIG. 2b is an enlarged schematic top view of a portion B of FIG. 2a; FIG. 2c is a schematic cross-sectional view of the structure in FIG. 2a taken along a cutting line CC′: FIG. 2d is another schematic top view of the display substrate according to an embodiment of the present disclosure. The display substrate has a display area 101 and a bezel area 102, and the bezel area 102 at least partially surrounds the display area 101, and display substrate includes: a base substrate 1 located in the display area 101 and the area 102; a plurality of pixel circuits 2 located on a side of the base substrate 1 and located in the display area 101; a plurality of light-emitting elements 3 located on a side of the plurality of pixel circuits 2 away from the base substrate 1 and located in the display area 101, the plurality of pixel circuits 2 being configured to drive the plurality of light-emitting elements 3 to emit light, at least one of the plurality of light-emitting elements 3 including a first electrode 31, a light-emitting layer 32, and a second electrode 33 disposed in this order away from the base substrate 1; a first signal line 4 located in the bezel area 102 and electrically connected to the second electrode 33; and a plurality of second signal lines 5 located on a side of the base substrate 1 and configured to be connected to a functional element 6, at least part of the second signal lines 5 are located in the bezel area 102, and an orthographic projection of each of at least part of the second signal lines 5 on the base substrate 1 overlaps with an orthographic projection of the first signal line 4 on the base substrate 1.

In some implementations, the orthographic projection of each of at least part of the second signal lines 5 on the base substrate 1 and the orthographic projection of the first signal line 4 on the base substrate 1 may be partially overlapped or completely overlapped.

In some implementations, referring to FIG. 2d, the second electrode 33 extends from the display area 101 to the bezel area 102, and orthographic projections of the second electrode 33 and the first signal line 4 on the base substrate 1 are partially overlapped.

Compared with the layout design scheme in FIG. 1c in the related art that the signal lines are arranged in the bezel area, in the present embodiment, the orthographic projection of each of at least part of the second signal lines 5 on the base substrate 1 is overlapped with the orthographic projection of the first signal line 4 on the base substrate 1, so that a space (in a width direction of the bezel area) occupied by the at least part of the second signal lines 5 in the bezel area 102 is overlapped with a space (in a width direction of the bezel area) occupied by the first signal line 4 in the bezel area 102, so that an additional space (in a width direction of the bezel area) occupied by the at least part of the second signal lines 5 in the bezel area 102 is reduced or at least part of the second signal lines 5 does not occupy an additional space (in a width direction of the bezel area) in the bezel area 102, thereby obtaining the effect of reducing the width of the bezel area 102, and being beneficial to realizing a narrow bezel or an extremely narrow bezel for the display substrate.

In some implementations, the first signal line 4 is a power line, such as a signal line with a signal voltage VSS, a signal line with a signal voltage VGH, or a signal line with a signal voltage VGL. In some implementations, the first signal line 4 may be another signal line, such as a signal line with a signal voltage Vinit for resetting the first electrode 31 of the light-emitting element 3 in the pixel circuit 2. The first signal line 4 arranged in the bezel area 102 and an occupied space thereof in the bezel area being common to the second signal line 5 is within the protection scope of the present disclosure.

In some implementations, the functional element 6 may be any functional element that requires a signal line to be led out from the bezel area 102, such as a photoelectric sensor, an antenna, NFC, or the like.

In some implementations, an orthographic projection of each of the plurality of second signal lines 5 on the base substrate 1 overlaps the orthographic projection of the first signal line 4 on the base substrate 1. The orthographic projection of each of the second signal lines 5 on the base substrate 1 and the orthographic projection of the first signal line 4 on the base substrate 1 may be partially overlapped or completely overlapped, that is, each second signal line 5 may be partially located in a space of the bezel area occupied by the first signal line 4, or each second signal line 5 may be completely located in the space of the bezel area occupied by the first signal line 4.

In some implementations, the orthographic projection of each second signal line 5 of the plurality of second signal lines 5 on the base substrate 1 is located within the orthographic projection of the first signal line 4 on the base substrate 1. That is, each second signal line 5 is completely located in the space of the bezel area occupied by the first signal line 4; for the plurality of second signal lines 5 arranged in parallel, an interval between any two adjacent second signal lines 5 is also located in the space of the bezel area occupied by the first signal line 4, so that the space, in the width direction of the bezel area, additionally occupied by the plurality of second signal lines 5 in the bezel area 102 is greatly reduced.

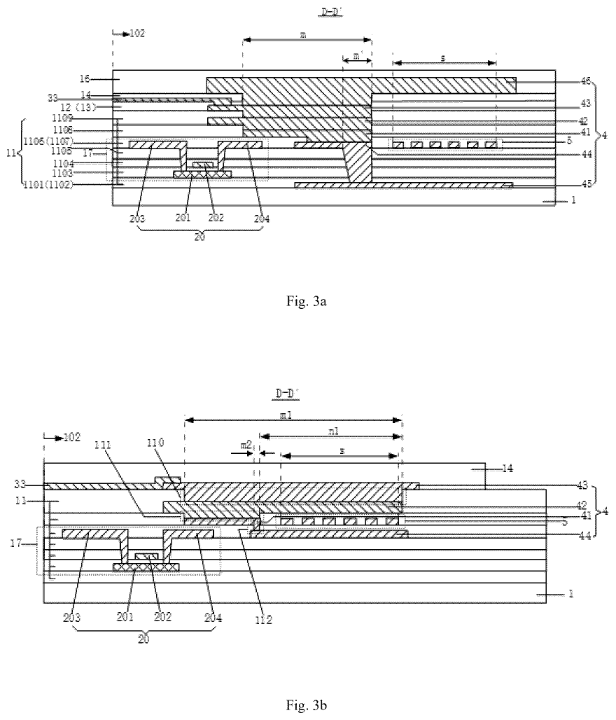

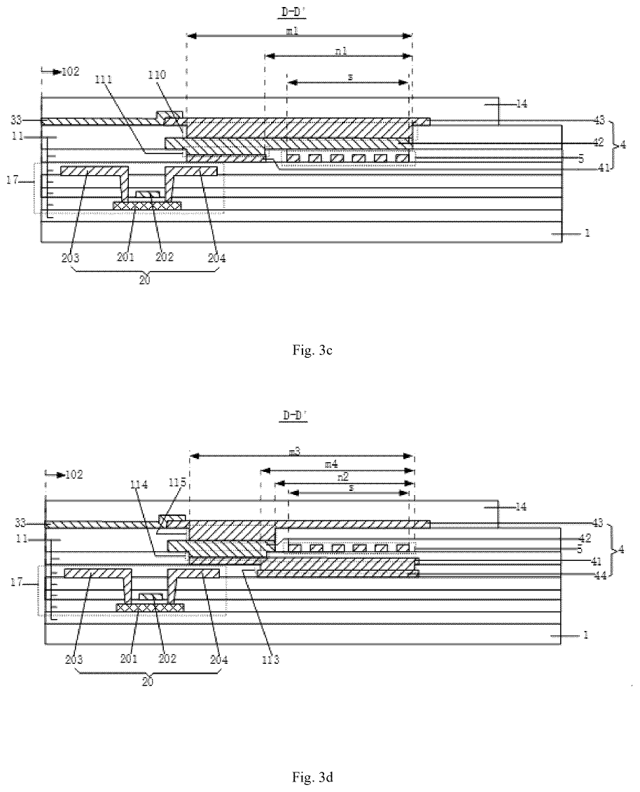

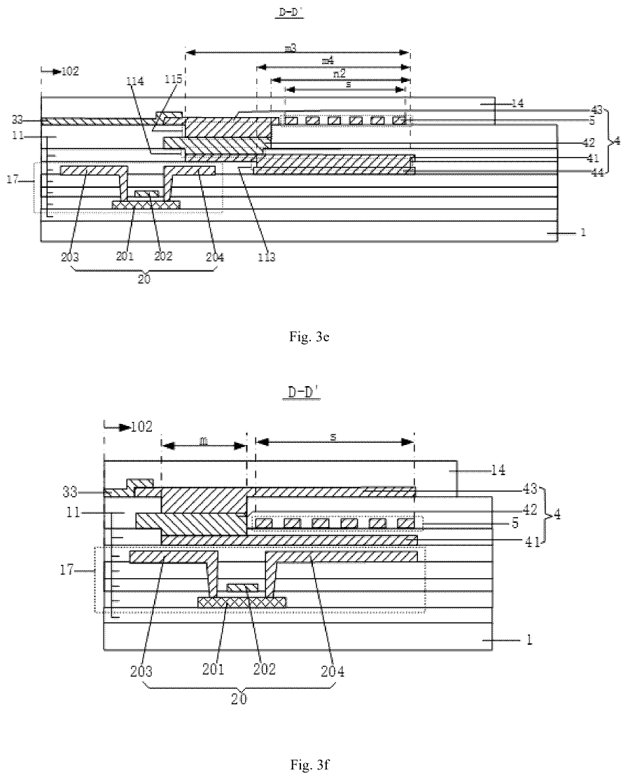

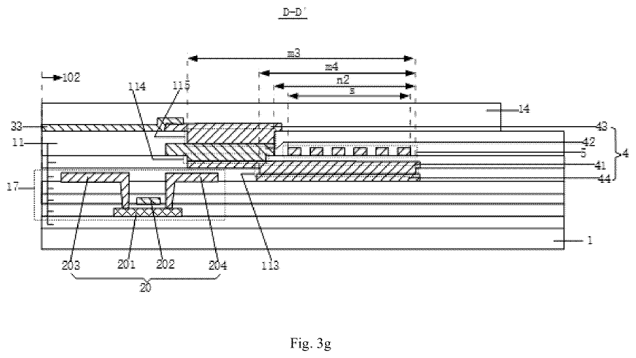

In some implementations, referring to FIGS. 3a, 3b, 3c, 3d, 3e, 3f and 3g, FIG. 3a is a schematic cross-sectional view of the display substrate in FIG. 2d taken along a cutting line DD′ according to an embodiment of the present disclosure; FIG. 3b is another schematic cross-sectional view of the display substrate in FIG. 2d taken along the cutting line DD′ according to an embodiment of the present disclosure; FIG. 3c is another schematic cross-sectional view of the display substrate in FIG. 2d taken along the cutting line DD′ according to an embodiment of the present disclosure; FIG. 3d is another schematic cross-sectional view of the display substrate in FIG. 2d taken along the cutting line DD′ according to an embodiment of the present disclosure; FIG. 3e is another schematic cross-sectional view of the display substrate in FIG. 2d taken along the cutting line DD′ according to an embodiment of the present disclosure; FIG. 3f is another schematic cross-sectional view of the display substrate in FIG. 2d taken along the cutting line DD′ according to an embodiment of the present disclosure; FIG. 3g is another schematic cross-sectional view of the display substrate in FIG. 2d taken along the cutting line DD′ according to an embodiment of the present disclosure, where the first signal line 4 includes at least two conductive layers located in different layers and electrically connected to each other, and the at least two conductive layers include a first conductive layer 41 and a second conductive layer 42.

In some implementations, the first signal line 4 is arranged as two conductive layer located in different layers and electrically connected with each other, the resistance of the first signal line 4 can be reduced, thus the display power consumption of the display substrate can be reduced, and in this case, the picture displayed by the display substrate may be more even, improving the display effect of the display substrate.

In some implementations, referring to FIG. 3a, the second electrode 33 is electrically connected to a third conductive layer 43; referring to FIG. 3b, the second electrode 33 is electrically connected to the third conductive layer 43; referring to FIG. 3c, the second electrode 33 is electrically connected to the third conductive layer 43; referring to FIG. 3d, the second electrode 33 is electrically connected to the third conductive layer 43; referring to FIG. 3e, the second electrode 33 is electrically connected to the third conductive layer 43; referring to FIG. 3f, the second electrode 33 is electrically connected to the third conductive layer 43; referring to FIG. 3g, the second electrode 33 is electrically connected to the third conductive layer 43.

In some implementations, referring to FIGS. 3b, 3c, 3d, 3e, 3f, and 3g, one of the first conductive layer 41 and the second conductive layer 42 is located in the same layer as at least part of the second signal lines 5, and an projection of the other of the first conductive layer 41 and the second conductive layer 42 on the base substrate 1 overlaps with an orthographic projection of each of at least part of the second signal lines 5 on the base substrate 1.

In some implementations, referring to FIGS. 3b and 3c, the second conductive layer 42 is located on a side of the first conductive layer 41 away from the base substrate 1, the first conductive layer 41 and at least part of the second signal lines 5 are located in a same layer, and an orthographic projection of the second conductive layer 42 on the base substrate 1 overlaps with an orthographic projection of each of at least part of the second signal lines 5 on the base substrate 1.

The second conductive layer 42 may play a role of shielding a signal for the at least part of the second signal lines 5, and ensure that the at least part of the second signal lines 5 is not interfered by a signal in another signal line located on a side of the second signal lines 5 away from the base substrate 1. The first conductive layer 41 and at least part of the second signal lines 5 being located in a same layer means that the first conductive layer 41 and the at least part of the second signal lines 5 are formed simultaneously by a single patterning process, and the first conductive layer 41 and the at least part of the second signal lines 5 are not necessarily located on a same plane in structure.

In some implementations, referring to FIGS. 3d, 3e, 3f and 3g, the second conductive layer 42 is located on a side of the first conductive layer 41 away from the base substrate 1, the second conductive layer 42 and at least part of the second signal lines 5 are located in a same layer, and an orthographic projection of the first conductive layer 41 on the base substrate 1 overlaps with an orthographic projection of each of at least part of the second signal lines 5 on the base substrate 1.

The first conductive layer 41 may play a role of shielding a signal for the at least part of the second signal lines 5, and ensure that the at least part of the second signal lines 5 is not interfered by signals in another signal line located on a side of the second signal lines close to the base substrate 1. The second conductive layer 42 and the at least part of the second signal lines 5 being located in a same layer means that the second conductive layer 42 and the at least part of the second signal lines 5 are formed simultaneously by a single patterning process, and the second conductive layer 42 and the at least part of the second signal lines 5 are not necessarily located on a same plane in structure.

In some implementations, referring to FIGS. 3a, 3b, 3c, 3d, 3e, 3f and 3g, the first signal line 4 further includes a third conductive layer 43 located on a side of the first conductive layer 41 and the second conductive layer 42 away from the base substrate 1, and the first conductive layer 41, the second conductive layer 42 and the third conductive layer 43 are electrically connected together.

In some implementations, referring to FIGS. 3b, 3c, 3d, 3e and 3f, an orthographic projection of the third conductive layer 43 on the base substrate 1 overlaps with the orthographic projection of at least part of the second signal lines 5 on the base substrate 1.

The third conductive layer 43 may play a role of shielding a signal for the at least part of the second signal lines 5, and ensure that the at least part of the second signal lines 5 is not interfered by a signal in another signal line located on a side of the second signal lines 5 away from the base substrate 1.

In some implementations, referring to FIG. 3g, the orthographic projection of the third conductive layer 43 on the base substrate 1 does not overlap with an orthographic projection of each of at least part of the second signal lines 5 on the base substrate 1.

In some implementations, referring to FIGS. 3b, 3d, 3e and 3g, the first signal line 4 further includes a fourth conductive layer 44 on a side of the first conductive layer 41 and the second conductive layer 42 close to the base substrate 1, the fourth conductive layer 44, the first conductive layer 41 and the second conductive layer 42 are sequentially stacked away from the base substrate 1, and an orthographic projection of the fourth conductive layer 44 on the base substrate 1 overlaps with an orthographic projection of at least part of the second signal lines 5 on the base substrate 1.

The fourth conductive layer 44 may play a role of shielding a signal for the at least part of the second signal lines 5, and ensure that the at least part of the second signal lines 5 is not interfered by a signal in another signal line located on a side of the second signal lines close to the base substrate 1.

In some implementations, referring to FIG. 3a, the first signal line 4 further includes a fourth conductive layer 44 and a fifth conductive layer 45 located on a side of the first conductive layer 41 and the second conductive layer 42 close to the base substrate 1, and a third conductive layer 43 and a sixth conductive layer 46 located on a side of the first conductive layer 41 and the second conductive layer 42 away from the base substrate 1, where the fifth conductive layer 45, the fourth conductive layer 44, the first conductive layer 41, the second conductive layer 42, the third conductive layer 43, and the sixth conductive layer 46 are sequentially stacked away from the base substrate 1, the first conductive layer 41, the second conductive layer 42, the third conductive layer 43, the fourth conductive layer 44, the fifth conductive layer 45, and the sixth conductive layer 46 are electrically connected together, at least part of the second signal lines 5 is located in the same layer as the fourth conductive layer 44, and orthographic projections of the fifth conductive layer 45 and the sixth conductive layer 46 on the base substrate 1 overlap with an orthographic projection of each of the at least part of the second signal lines 5 on the base substrate 1.

The fifth conductive layer 45 and the sixth conductive layer 46 may play a role of shielding a signal for the at least part of the second signal lines 5, and ensure that the at least portion 5 is not interfered by a signal in another signal line located on a side of the second signal lines close to the base substrate 1 and a signal in another signal line located on a side of the second signal lines away from the base substrate 1.

In some implementations, the fourth conductive layer 44 being located in the same layer as the at least part of the second signal lines 5 means that the fourth conductive layer 44 and the at least part of the second signal lines 5 are formed simultaneously by a single patterning process, and the fourth conductive layer 44 and the at least part of the second signal lines 5 are not necessarily located on a same plane in structure.

In some implementations, referring to FIG. 3a and FIG. 2c, the display substrate further includes a first connection electrode 7, a second connection electrode 8, and at least one touch electrode layer 9 on a side of the pixel circuits 2 away from the base substrate 1, and a shielding layer 10 on a side of the pixel circuits 2 close to the base substrate 1, the pixel circuit 2 includes at least one thin film transistor 20, the thin film transistor 20 includes an active layer 201 located on a side of the base substrate 1, a gate electrode 202 located on a side of the active layer 201 away from the base substrate 1, and a source electrode 203 and a drain electrode 204 located on a side of the gate electrode 202 away from the base substrate 1; an orthographic projection of the shielding layer 10 on the base substrate 1 is overlapped with an orthographic projection of the active layer 201 on the base substrate 1; the first connection electrode 7 is located on a side of the thin film transistor 20 away from the base substrate 1 and is electrically connected with the thin film transistor 20; the second connection electrode 8 is located on a side of the first connection electrode 7 away from the base substrate 1 and is electrically connected with the first connection electrode 7; the light-emitting element 3 is located on a side of the second connection electrode 8 away from the base substrate 1 and is electrically connected with the second connection electrode 8; the at least one touch electrode layer 9 is located on a side of the light-emitting element 3 away from the base substrate 1; the first conductive layer 41 is located in the same layer as the first connection electrode 7; the second conductive layer 42 and the second connection electrode 8 are located in a same layer; the third conductive layer 43 and the first electrode 31 are located in a same layer; the fourth conductive layer 44 is located in the same layer as the source electrode 203 and the drain electrode 204 of the thin film transistor; the fifth conductive layer 45 is located in the same layer as the shielding layer 10; the sixth conductive layer 46 is located in the same layer as any one of the at least one touch electrode layer 9.

In some implementations, the shielding layer 10 may be made of a metal material.

In some implementations, the two conductive film layers located in the same layer mean that patterns of the two conductive film layer are formed simultaneously by a single patterning process, and the patterns of the two conductive film layers are not necessarily located on a same plane in structure.

In some implementations, the orthographic projection of the shielding layer 10 on the base substrate 1 is overlapped with the orthographic projection of the active layer 201 on the base substrate 1, so that the output capability of the thin film transistor 20 can be stabilized, the characteristics of the device can be adjusted, the floating effect of the thin film transistor 20 can be suppressed, the short channel effect of the thin film transistor 20 can be suppressed, and the thermal effect of the thin film transistor 20 can be improved.

In some implementations, referring to FIG. 3a and FIG. 2c, an insulating layer 11 is disposed between any two adjacent conductive layers, and the insulating layer 11 may be an inorganic insulating layer made of, for example, silicon nitride, silicon oxide, a silicon oxynitride, or the like, or an organic insulating layer made of, for example, polyimide, polyurethane, or the like.

In some implementations, referring to FIGS. 3a to 3g and FIG. 2c, a pixel defining layer 12 and a spacer layer 13 are further disposed on a side of the first electrode 31 away from the base substrate 1, an opening is formed in the pixel defining layer 12 and the spacer layer 13, and at least portion of the light-emitting layer 32 and at least portion of the second electrode 33 are located in the opening. The display substrate further includes an encapsulation layer 14 located on a side of the light-emitting element 3 away from the base substrate 1 for encapsulating the light-emitting element. The encapsulation layer 14 includes a first inorganic encapsulation layer, an organic encapsulation layer, and a second inorganic encapsulation layer, which are sequentially stacked. The encapsulation layer 14 is provided with a buffer layer 15 on a side thereof away from the base substrate 1, the at least one touch electrode layer 9 is located on a side of the buffer layer 15 away from the base substrate 1, and a protective layer 16 is further disposed on a side of the touch electrode layer 9 away from the base substrate 1 for protecting the touch electrode layer 9.

In some implementations, referring to FIG. 2b, FIG. 3a, FIG. 3b, FIG. 3c, FIG. 3d, FIG. 3e and FIG. 3g, the display substrate further includes a gate driving circuit (GOA circuit) 17, the gate driving circuit 17 is located in the bezel area 102, and an orthographic projection of the gate driving circuit 17 on the base substrate 1 is partially overlapped with an orthographic projection of the first signal line 4 on the base substrate 1.

In some implementations, the GOA circuit may be an EM GOA circuit (emission control GOA circuit) or a Gate GOA circuit (Gate driver GOA circuit), and only one transistor is used for representing the GOA circuit in each figure, and the GOA circuit is not shown in its entirety.

In some implementations, referring to FIG. 3f, the orthographic projection of the first signal line 4 on the base substrate 1 is located within an orthographic projection of the gate driving circuit 17 on the base substrate 1.

In some implementations, referring to FIG. 2b, FIG. 3a to FIG. 3g, the gate driving circuit 17 includes at least one thin film transistor 20, and same ones of the film layers (e.g., the active layer 201, the gate electrode 202, the source electrode 203, and the drain electrode 204) of the thin film transistor 20 in the gate driving circuit 17 and the film layers (e.g., the active layer 201, the gate electrode 202, the source electrode 203, and the drain electrode 204) of the thin film transistor 20 in the pixel circuit 2 are simultaneously manufactured by a single manufacturing process.

In some implementations, referring to FIG. 2a, the bezel area 102 includes a first bezel area 102a, a second bezel area 102b, a third bezel area 102c and a fourth bezel area 102d sequentially disposed around the display area 101, the functional element 6 is located in the display area 101, the functional element 6 is disposed close to the first bezel area 102a, the functional element 6 is connected to the second signal lines 5 through a plurality of signal leads 18, respectively, the signal leads 18 extend from a position where the functional element 6 is located to the first bezel area 102a and are connected with the second signal lines 5 located in the first bezel area 102a. The display substrate further includes signal input pads 19, the signal input pads 19 are located in the third bezel area 102c, and the plurality of second signal lines 5 extend from the first bezel area 102a to the third bezel area 102c through the second bezel area 102b, and are connected to the signal input pads 19. Referring to FIG. 2d, the display substrate further includes a bonding pad 26 located in the third bezel area 102c, the first signal line 4 extends to the third bezel area 102c and is connected to the bonding pad 26, and the bonding pad 26 is used for being bonded to a peripheral circuit board (e.g., FPC (flexible printed circuit)) so that the peripheral circuit board can provide a signal (e.g., VSS signal) to the first signal line 4.

In some implementations, the plurality of signal leads 18 and signal input pads 19 may be prepared by a single preparation process with any conductive film layer in the pixel circuits 2, so that the preparation of the signal leads 18 and the signal input pads 19 does not require adding a preparation process step to the preparation process of the display substrate.

In some implementations, referring to FIG. 2a, the first signal line 4 is disposed in at least the first bezel area 102a, the second bezel area 102b and the fourth bezel area 102d, and the orthographic projection of each of the at least part of the second signal lines 5 on the base substrate I overlaps with an orthographic projection of a portion of the first signal line 4 disposed in the second bezel area 102b on the base substrate 1. Therefore, the width of the space occupied by the second signal line 5 in the second bezel area 102b can be reduced, thus the width of the second bezel area 102b can be reduced.

In some implementations, the functional element 6 is a photoelectric sensor, the photoelectric sensor is accommodated in the bezel of the camera installation hole 21 formed in the display area 101, and the photoelectric sensor may be used for controlling the display brightness of the display screen or controlling the display screen to be turned off when making or receiving a call. The photoelectric sensor includes at least two conductive film layers, and the at least two conductive film layers and any conductive film layer in the pixel circuit 2 may be prepared through a single preparation process, so that the preparation of the photoelectric sensor does not need to add a preparation process step to the preparation process of the display substrate.

In some implementations, alternatively, the functional element 6 may be an antenna distributed in the display area 101 or an NFC device integrated in the display area 101, and the antenna or the NFC device may be provided at any position in the display area 101, which is not limited herein.

In a second aspect, an embodiment of the present disclosure further provides a display substrate, referring to FIG. 2a, FIG. 2b, and FIG. 2c, the display substrate has a display area 101 and a bezel area 102, the bezel area 102 at least partially surrounding the display area 101, and the display substrate includes a base substrate 1, a plurality of pixel units, a functional element 6, a first signal line 4, and at least one second signal line 5. Each pixel unit includes a pixel circuit 2 and a light-emitting element 3, the light-emitting element 3 is located on a side of the pixel circuit 2 away from the base substrate 1, and the pixel circuit 2 is electrically connected with the light-emitting element 3. The pixel unit, the functional member 6, the first signal line 4 and the second signal line 5 each are located on a side of the base substrate 1; the pixel unit and the functional element 6 are located in the display area 101, and the pixel unit at least partially surrounds the functional element 6. The first signal line 4 and the second signal line 5 are located in the bezel area 102. The first signal line 4 is electrically connected to a second electrode, e.g., a cathode, of the light-emitting element in the pixel unit, and the second signal line 5 are electrically connected to the functional element 6. The first signal line 4 includes at least two conductive layers, the at least two conductive layers are located in different layers, an insulating layer 11 is disposed between any two adjacent conductive layers, and any two adjacent conductive layers are connected through a via hole formed in the insulating layer 11. The second signal line 5 is disposed in the same layer as one of the at least two conductive layers, and an orthographic projection of each second signal line 5 on the base substrate 1 overlaps with an orthographic projection of at least one of the at least two conductive layers on the base substrate 1.

The orthographic projection of each second signal line 5 on the base substrate 1 and the orthographic projection of at least one of the at least two conductive layers on the base substrate 1 may be partially overlapped or completely overlapped.

Compared with the layout design scheme that the signal lines are arranged in the bezel area in FIG. 1c in the related art, in the present embodiment, the orthographic projection of each second signal line 5 on the base substrate 1 is overlapped with the orthographic projection of the at least one of the at least two conductive layers on the base substrate 1, so that a apace occupied by the second signal line 5 in the bezel area 102 is overlapped with a space occupied by the first signal line 4 in the bezel area 102, so that an additional space, in a width direction of the bezel area 120, occupied by the second signal line 5 in the bezel area 102 is reduced or the second signal line 5 does not occupy an additional space in the bezel area 102 in a width direction of the bezel area 102, thereby obtaining the effect of reducing the width of the bezel area 102, and being beneficial to realizing a narrow bezel or an extremely narrow bezel for the display substrate.

In some implementations, referring to FIGS. 3b, 3c, 3d and 3e, the first signal line 4 includes at least three conductive layers, two adjacent ones of the at least three conductive layers form a group, the at least three conductive layers may form at least two groups, and orthographic projection of the second signal line 5 on the base substrate 1 overlaps an orthographic projection of a connection via hole connecting at least two adjacent conductive layers of at least one of the at least two groups on the base substrate 1.

In some implementations, referring to FIGS. 3b and 3c, at least two of the at least three conductive layers are located on a side of the second signal line 5 away from the base substrate 1, and any two adjacent ones of the at least three conductive layers are connected through a first via hole 110 provided in the insulating layer 11; the orthographic projection of the second signal line 5 on the base substrate 1 is located within an orthographic projection of the first via hole 110 on the base substrate 1.

Referring to FIGS. 3b and 3c, the conductive layers on the side of the second signal line 5 away from the base substrate I may play a role of shielding a signal for the second signal line 5, and ensure that the second signal line 5 is not interfered by a signal in another signal line on the side thereof away from the base substrate 1.

In some implementations, referring to FIGS. 3b and 3c, the conductive layer in the same layer as the second signal line 5 is connected with the conductive layer adjacent to the second signal line 5 and located on a side of the second signal line 5 away from the base substrate 1 through a second via hole 111 provided in the insulating layer 11, and an orthographic projection of the second via hole 111 on the base substrate 1 is located within the orthographic projection of the first via hole 110 on the base substrate 1.

Referring to FIGS. 3b and 3c, the second signal line 5 occupies a part of the space of the connection via hole connecting the conductive layer of the first signal line 4 that is in the same layer as the second signal line 5 with the conductive layer of the first signal line 4 that is adjacent to the second signal line 5, that is, a width of the connection via hole connecting the conductive layer of the first signal line 4 that is in the same layer as the second signal lines 5 with the conductive layer of the first signal line 4 that is adjacent to the conductive layer in the same layer as the second signal line 5 is reduced. The width of the connection via hole is a dimension of the connection via hole along a width direction of the second signal line 5 (in a case where only one second signal line 5 is provided) or a dimension of the connection via hole along a direction in which a plurality second signal lines 5 (in a case where a plurality of second signal lines 5 are provided) are arranged.

In some implementations, referring to FIGS. 3b and 3c, the first signal line 4 includes a first conductive layer 41, a second conductive layer 42, and a third conductive layer 43, the first conductive layer 41, the second conductive layer 42, and the third conductive layer 43 are sequentially stacked away from the base substrate 1. The second signal line 5 is located in the same layer as the first conductive layer 41; the orthographic projection of the second signal line 5 on the base substrate 1 is located within the orthographic projection of the first via hole 110 connecting the second conductive layer 42 with the third conductive layer 43 on the base substrate 1; the orthographic projection of the second via hole 111 connecting the first conductive layer 41 with the second conductive layer 42 on the base substrate 1 is located within the orthographic projection of the first via hole 110 on the base substrate 1. The second signal line 5 occupies a part of the space (width) of the second via hole 111, i.e., a width of the second via hole 111 is reduced. Referring to FIGS. 3b and 3c, the widths of the second via hole 111 and the first via hole 110 are both m1, and in the present embodiment, the second signal line 5 occupies a part, which is n1, of the width of the second via hole 111, so that the width of the second via hole 111 is reduced to (m1−n1).

In some implementations, referring to FIG. 3b, at least one of the at least three conductive layers is located on a side of the second signal line 5 close to the base substrate 1, the conductive layer in the same layer as the second signal line 5 is connected with the conductive layer located on the side of the second signal line 5 close to the base substrate 1 and adjacent to the second signal line 5 through a third via hole 112 provided in the insulating layer 11, and an orthographic projection of the third via hole 112 on the base substrate 1 is located within the orthographic projection of the first via hole 110 on the base substrate 1.

In some implementations, referring to FIG. 3b, the first signal line 4 further includes a fourth conductive layer 44, the second signal line 5 is located in the same layer as the first conductive layer 41, the fourth conductive layer 44 is located on a side of the second signal line 5 close to the base substrate 1 and adjacent to the first conductive layer 41, the first conductive layer 41 is connected with the fourth conductive layer 44 through a third via hole 112, and an orthographic projection of the third via hole 112 on the base substrate 1 is located within the orthographic projection of the first via hole 110 on the base substrate 1.

In some implementations, referring to FIGS. 3b and 3c, a plurality of second signal lines 5 are provided, and the second signal lines 5 are distributed at intervals; a total distribution width s of orthographic projections of the second signal lines 5 on the base substrate 1 is greater than the orthographic projection width, i.e., (m1−n1), of the second via hole 111 on the base substrate 1, and the total distribution width s of the orthographic projections of the second signal lines 5 on the base substrate 1 is greater than a width, i.e., m2, of the orthographic projection of the third via hole 112 on the base substrate 1.

In some implementations, the total distribution width of the orthographic projections of the second signal lines 5 on the base substrate 1 refers to a sum of the widths of the orthographic projections of the second signal lines 5 on the base substrate 1 and widths of orthographic projections of intervals between every two adjacent second signal lines 5 on the base substrate 1. The width of the orthographic projection of the second via hole 111 on the base substrate 1 is a dimension of the second via hole 111 along a direction in which the second signal lines 5 are arranged. The width of the orthographic projection of the third via hole 112 on the base substrate 1 is a dimension of the third via hole 112 in a direction in which the second signal lines 5 are arranged.

In some implementations, referring to FIGS. 3d, 3e and 3g, at least two of the at least three conductive layers are located on a side of the second signal lines 5 close to the base substrate 1, and any two adjacent ones of the at least two conductive layers are connected together through a fourth via hole 113 provided in the insulating layer 11; orthographic projections of the second signal lines 5 on the base substrate 1 overlap an orthographic projection of the fourth via hole 113 on the base substrate 1.

The conductive layer on the side of the second signal lines 5 close to the base substrate 1 may play a role of shielding a signal for the second signal lines 5, so as to ensure that the second signal lines 5 are not interfered by a signal in another signal line on the side of the second signal lines close to the base substrate 1.

In some implementations, referring to FIGS. 3d and 3e, at least one of the at least three conductive layers is located on a side of the second signal lines 5 away from the base substrate 1, and orthographic projections of the fourth via hole 113 and the second signal lines 5 on the base substrate 1 are located within an orthographic projection of the conductive layer on the side of the second signal lines 5 away from the base substrate 1 on the base substrate 1.

The conductive layer on the side of the second signal lines 5 away from the base substrate 1 may play a role of shielding a signal for the second signal lines 5, so as to ensure that the second signal lines 5 are not interfered by a signals in another signal line on the side of the second signal lines 5 away from the base substrate 1.

In some implementations, referring to FIGS. 3d, 3e and 3g, the conductive layer in the same layer as the second signal lines 5 is connected with the conductive layer located on the side of the second signal lines 5 close to the base substrate 1 and adjacent to the second signal lines 5 through a fifth via hole 114 provided in the insulating layer 11; the conductive layer in the same layer as the second signal lines 5 is connected with the conductive layer located on the side of the second signal lines 5 away from the base substrate 1 and adjacent to the second signal lines 5 through a sixth via hole 115 provided in the insulating layer 11; orthographic projections of the fifth via hole 114 and the sixth via hole 115 on the base substrate 1 coincide.

Referring to FIGS. 3d, 3e and 3g, the second signal lines 5 occupies a part of the space of the connection via hole connecting the conductive layer of the first signal line 4 that is in the same layer as the second signal lines 5 with the conductive layer of the first signal line 4 that is adjacent to the second signal lines 5, that is, a width of the connection via hole connecting the conductive layer of the first signal line 4 that is in the same layer as the second signal lines 5 with the conductive layer of the first signal line 4 that is adjacent to the conductive layer in the same layer as the second signal lines 5 is reduced. The width of the connection via hole is a dimension of the connection via hole along a width direction of the second signal line 5 (in a case where only one second signal line 5 is provided) or a dimension of the connection via hole along a direction in which the second signal lines 5 are arranged.

In some implementations, referring to FIGS. 3d, 3e and 3g, the first signal line 4 includes a fourth conductive layer 44, a first conductive layer 41, a second conductive layer 42 and a third conductive layer 43, the fourth conductive layer 44, the first conductive layer 41, the second conductive layer 42 and the third conductive layer 43 are sequentially stacked away from the base substrate 1. Referring to FIGS. 3d and 3g, the second signal lines 5 are located in the same layer as the second conductive layer 42. Referring to FIG. 3e, the second signal lines 5 and the third conductive layer 43 are located in a same layer. The fourth conductive layer 44 and the first conductive layer 41 are located on a side of the second signal lines 5 close to the base substrate 1, and the fourth conductive layer 44 is connected with the first conductive layer 41 through a fourth via hole 113; the second conductive layer 42 is connected with the first conductive layer 41 through a fifth via hole 114; the second conductive layer 42 is connected with the third conductive layer 43 through a sixth via hole 115. The second signal line 5 occupies a part of each of the spaces (widths) of the fifth via hole 114 and the sixth via hole 115, i.e., the widths of the fifth via hole 114 and the sixth via hole 115 are reduced. Referring to FIGS. 3d, 3e and 3g, in the present embodiment, the second signal line 5 occupies a part, which is n2, of a width of each of the fifth via hole 114 and the sixth via hole 115, and the widths of the fifth via hole 114 and the sixth via hole 115 are each reduced to (m3−n2).

In some implementations, referring to FIGS. 3d, 3e, and 3g, the widths of the fourth via hole 113, the fifth via hole 114, and the sixth via hole 115 may be further reduced to achieve further reduction of the width of the bezel area 102 of the display substrate. For example, the widths of the fourth via hole 113, the fifth via hole 114 and the sixth via hole 115 may be reduced to 4-5 μm.

In some implementations, referring to FIGS. 3d, 3e and 3g, a plurality of second signal lines 5 are provided, and the second signal lines 5 are distributed at intervals; a total distribution width, i.e., s, of the orthographic projections of the plurality of second signal lines 5 on the base substrate 1 is greater than the width, i.e., (m3−n2), of the orthographic projection of the fifth via hole 114 on the base substrate 1.

In some implementations, a total distribution width, i.e., s, of the orthographic projections of the second signal lines 5 on the base substrate 1 refers to a sum of the widths of second signal lines 5 on the base substrate 1 and widths of orthographic projections of intervals between every two adjacent second signal lines 5 on the base substrate 1. A width, i.e., m4, of an orthographic projection of the fourth via hole 113 on the base substrate 1 is a dimension of the fourth via hole 113 in a direction in which the second signal lines 5 are arranged. The width, i.e., (m3−n2) of the orthographic projection of each of the fifth via hole 114 and the sixth via hole 115 on the base substrate 1 is a dimension of each of the fifth via hole 114 and the sixth via hole 115 in a direction in which the second signal lines 5 are arranged.

In some implementations, referring to FIGS. 3a and 3f, orthographic projections of the second signal lines 5 on the base substrate 1 are not overlapped with an orthographic projection of a connection via hole connecting any two adjacent ones of the at least three conductive layers on the base substrate 1.

Referring to FIGS. 3a and 3f, the second signal line 5 occupies a part of the space (width) of the connection via hole connecting any two adjacent conductive layers of the at least three conductive layers, that is, the width of the connection via hole connecting any two adjacent conductive layers is reduced. The width of the connection via hole is a dimension of the connection via hole along a width direction of the second signal line 5 (in a case where only one second signal line 5 is provided) or a dimension of the connection via hole in a direction in which the second signal lines 5 are arranged.

In some implementations, referring to FIGS. 3a and 3f, a plurality of second signal lines 5 are provided, and the second signal lines 5 are distributed at intervals; a total distribution width, i.e., s, of the orthographic projections of the second signal lines 5 on the base substrate 1 is larger than a width, i.e., m (m′), of the orthographic projection of the connection via hole connecting any two adjacent ones of the at least three conductive layers on the base substrate 1.

In some implementations, referring to FIG. 3a, the first signal line 4 includes a fifth conductive layer 45, a fourth conductive layer 44, a first conductive layer 41, a second conductive layer 42, a third conductive layer 43, and a sixth conductive layer 46, the fifth conductive layer 45, the fourth conductive layer 44, the first conductive layer 41, the second conductive layer 42, the third conductive layer 43, and the sixth conductive layer 46 are sequentially stacked away from the base substrate 1, where the second signal lines 5 and the fourth conductive layer 44 are located in a same layer. The second signal lines 5 occupy a part of a space (width) of the connection via hole connecting any two adjacent ones of the fifth conductive layer 45, the fourth conductive layer 44, the first conductive layer 41, the second conductive layer 42, the third conductive layer 43, and the sixth conductive layer 46, that is, the width of the connection via hole connecting any two adjacent ones of the fifth conductive layer 45, the fourth conductive layer 44, the first conductive layer 41, the second conductive layer 42, the third conductive layer 43, and the sixth conductive layer 46 is reduced.

In some implementations, referring to FIG. 3f, the first signal line 4 includes a first conductive layer 41, a second conductive layer 42, and a third conductive layer 43, the first conductive layer 41, the second conductive layer 42, and the third conductive layer 43 are sequentially stacked away from the base substrate 1, where the second signal lines 5 are located in the same layer as the second conductive layer 42. The second signal lines 5 occupy a part of a space (width) of the connection via hole connecting any two adjacent ones of the first conductive layer 41, the second conductive layer 42, and the third conductive layer 43, that is, the width of the connection via hole connecting any two adjacent ones of the first conductive layer 41, the second conductive layer 42, and the third conductive layer 43 is reduced.

In some implementations, a minimum width of the connection via hole connecting any two adjacent conductive layers of the first signal line 4 is in a range from 4 micrometers to 5 micrometers, that is, it is enough as long as the minimum width of the connection via hole that can be achieved by the manufacturing process is ensured.

In some implementations, referring to FIGS. 3a, 3b, 3d and 3f, of the at least two conductive layers, the orthographic projection of which on the base substrate 1 are overlapped with the orthographic projections of the second signal lines 5 on the base substrate 1, at least one conductive layer is located on a side of the second signal lines 5 away from the base substrate 1, and at least one conductive layer is located on a side of the second signal lines 5 close to the base substrate 1.

The conductive layer on the side of the second signal lines 5 away from the base substrate 1 may play a role of shielding a signal for the second signal lines 5, so as to ensure that the second signal lines 5 are not interfered by a signals in another signal line on the side of the second signal lines 5 away from the base substrate 1. The conductive layer on the side of the second signal lines 5 close to the base substrate 1 may play a role of shielding a signal for the second signal lines 5, and ensure that the second signal lines 5 are not interfered by a signal in another signal line on the side close to the base substrate 1.

In some implementations, referring to FIGS. 3c and 3g, the at least two conductive layers, the orthographic projections of which on the base substrate 1 are overlapped with the orthographic projections of the second signal lines 5 on the base substrate 1 are located on a side of the second signal lines 5 away from the base substrate 1 or on a side of the second signal lines 5 close to the base substrate 1.

In some implementations, the pixel unit includes multiple layers of conductive patterns, and the at least two conductive layers of the first signal line 4 are respectively disposed in the same layer as the conductive patterns in indifferent layers.

In some implementations, referring to FIG. 2c, the display substrate further includes a first connection electrode 7, a second connection electrode 8, and at least one touch electrode layer 9 located on a side of the pixel circuit 2 away from the base substrate 1, and a shielding layer 10 located on a side of the pixel circuit 2 close to the base substrate 1, the pixel circuit 2 includes at least one thin film transistor 20, the thin film transistor 20 includes an active layer 201 located on a side of the base substrate 1, a gate electrode 202 located on a side of the active layer 201 away from the base substrate 1, and a source electrode 203 and a drain electrode 204 located on a side of the gate electrode 202 away from the base substrate 1. An orthographic projection of the shielding layer 10 on the base substrate 1 is overlapped with an orthographic projection of the active layer 201 on the base substrate 1. The first connection electrode 7 is located on a side of the thin film transistor 20 away from the base substrate 1 and is electrically connected with the thin film transistor 20. The second connection electrode 8 is located on a side of the first connection electrode 7 away from the base substrate 1 and is electrically connected with the first connection electrode 7. A light-emitting element 3 is located on a side of the second connection electrode 8 away from the base substrate 1 and is electrically connected with the second connection electrode 8. The at least one touch electrode layer 9 is located on a side of the light-emitting element 3 away from the base substrate 1. The first conductive layer 41 is located in the same layer as the first connection electrode 7. The second conductive layer 42 is located in the same layer as the second connection electrode 8. The third conductive layer 43 is located in the same layer as the first electrode 31; the fourth conductive layer 44 is located in the same layer as the source electrode 203 and/or the drain electrode 204. The fifth conductive layer 45 is located in the same layer as the shielding layer 10. The sixth conductive layer 46 is located in the same layer as any one of the at least on touch electrode layer 9.

In some implementations, referring to FIG. 3a, a plurality of insulating layers 11 respectively located in different layers are provided, and the plurality of insulating layers 11 include: a first buffer layer (Buffer1) 1101 located between the base substrate 1 and the shielding layer 10; a second buffer layer (Buffer1) 1102 located between the shielding layer 10 and the active layer 201; a first gate insulating layer (GI1) 1103 located between the active layer 201 and the gate electrode 202: a second gate insulating layer (GI2) 1104 and an interlayer dielectric layer (ILD) 1105 located between the gate electrode 202 and the source electrode 203 and the drain electrode 204: a passivation layer (PVX) 1106 and a first planarization layer (PLN1) 1107 located between the electrode 203 and the drain electrode 204 and the first connection electrode 7: a second planarization layer (PLN2) 1108 located between the first connection electrode 7 and the second connection electrode 8; and a third planarization layer (PLN3) 1109 located between the second connection electrode 8 and the first electrode 31.

In some implementations, referring to FIG. 3a, the first buffer layer (Buffer1) 1101, the second buffer layer (Buffer 2) 1102, the first gate insulating layer (GI1) 1103, the second gate insulating layer (GI2) 1104, the interlayer dielectric layer (ILD) 1105, the passivation layer (PVX) 1106, the first planarization layer (PLN1) 1107, the second planarization layer (PLN2) 1108, and the third planarization layer (PLN3) 1109, and the pixel defining layer 12, the spacer layer 13, the encapsulation layer 14, the buffer layer 15, and the protective layer 16 all extend from the display area 101 to the bezel area 102, respectively. The insulating layers 11 in FIGS. 3b to 3g are collectively denoted as insulating layer 11.

In some implementations, referring to FIGS. 3a to 3g and FIG. 2c, the display substrate further includes an encapsulation layer 14 located on a side of the pixel unit away from the base substrate 1, and an orthographic projection of the encapsulation layer 14 on the base substrate 1 covers at least orthographic projections of the pixel unit, the functional element 6, the first signal line 4 and the second signal lines 5 on the base substrate 1.

In some implementations, in the bezel area 102, a distance from an edge, which is away from the display area 101, of a metal wire farthest from the display area 101 to an edge of the display area 101 close to the metal wire may be reduced to be in a range from 0.6 mm to 1.1 mm.

Compared with the layout design scheme in FIG. 1c in the related art that the signal lines are arranged in the bezel area, in the present embodiment, the orthographic projection of each of at least part of the second signal lines 5 on the base substrate 1 is overlapped with the orthographic projection of the first signal line 4 on the base substrate 1, so that a space (in a width direction of the bezel area) occupied by the at least part of the second signal lines 5 in the bezel area 102 is overlapped with a space (in a width direction of the bezel area) occupied by the first signal line 4 in the bezel area 102, so that an additional space (in a width direction of the bezel area) occupied by the at least part of the second signal lines 5 in the bezel area 102 is reduced or at least part of the second signal lines 5 does not occupy an additional space (in a width direction of the bezel area) in the bezel area 102, thereby obtaining the effect of reducing the width of the bezel area 102, and being beneficial to realizing a narrow bezel or an extremely narrow bezel for the display substrate.

In a third aspect, an embodiment of the present disclosure further provides a display panel, which includes the display substrate in the foregoing embodiment.

With the display substrate in the forgoing embodiment, the display panel can realize a narrow bezel or an extremely narrow bezel.

The display panel provided by the embodiment of the present disclosure may be any product or component with a display function, such as an OLED panel, an OLED television, an OLED billboard, a display, a mobile phone, a navigator and the like.

It will be understood that the above implementations are merely exemplary implementations employed to illustrate the principles of the present disclosure, and the present disclosure is not limited thereto. It will be apparent to those skilled in the art that various changes and modifications can be made therein without departing from the spirit and scope of the present disclosure, and these changes and modifications are to be considered within the protective scope of the present disclosure.

1. A display substrate, comprising a display area and a bezel area, the bezel area at least partially surrounding the display area, wherein the display substrate comprises:
a base substrate located in the display area and the bezel area;
a plurality of pixel circuits located on a side of the base substrate and located in the display area;
a plurality of light-emitting elements located on a side of the pixel circuits away from the base substrate and located in the display area, the plurality of pixel circuits being configured to drive the plurality of light-emitting elements to emit light, at least one of the plurality of light-emitting elements comprising a first electrode, a light-emitting layer, and a second electrode sequentially disposed away from the base substrate;
a first signal line located in the bezel area and is electrically connected with the second electrode; and
a plurality of second signal lines located on a side of the base substrate and configured to be connected to a functional element, wherein at least part of the plurality of second signal lines are located in the bezel area, and an orthographic projection of each of the at least part of the plurality of second signal lines on the base substrate is overlapped with an orthographic projection of the first signal line on the base substrate.

2. The display substrate of claim 1, wherein an orthographic projection of each of the plurality of second signal lines on the base substrate is overlapped with the orthographic projection of the first signal line on the base substrate, and wherein
an orthographic projection of each of the plurality of second signal lines on the base substrate is located within the orthographic projection of the first signal line on the base substrate.

3. (canceled)

4. The display substrate of claim 1, wherein the first signal line comprises at least two conductive layers located in different layers and electrically connected with each other, the at least two conductive layers comprising a first conductive layer and a second conductive layer.

5. The display substrate of claim 4, wherein one of the first conductive layer and the second conductive layer is in the same layer as the at least part of the second signal lines, and an orthographic projection of the other of the first conductive layer and the second conductive layer on the base substrate is overlapped with the orthographic projection of each of the at least part of the second signal lines on the base substrate, or
the second conductive layer is located on a side of the first conductive layer away from the base substrate, the first conductive layer is located in the same layer as the at least part of the second signal lines, and an orthographic projection of the second conductive layer on the base substrate is overlapped with the orthographic projection of each of the at least part of the second signal lines on the base substrate, or
the second conductive layer is located on a side of the first conductive layer away from the base substrate, the second conductive layer is located in the same layer as the at least part of the second signal lines, and an orthographic projection of the first conductive layer on the base substrate is overlapped with the orthographic projection of each of the at least part of the second signal lines on the base substrate.

6-7. (canceled)

8. The display substrate of claims 5, wherein the first signal line further comprises a third conductive layer located on a side of the first conductive layer and the second conductive layer away from the base substrate, the first conductive layer, the second conductive layer, and the third conductive layer being electrically connected together.

9. The display substrate of claim 8, wherein an orthographic projection of the third conductive layer on the base substrate is overlapped with the orthographic projection of each of the at least part of the second signal lines on the base substrate, and wherein
the first signal line further comprises a fourth conductive layer located on a side of the first conductive layer and the second conductive layer close to the base substrate, the fourth conductive layer, the first conductive layer and the second conductive layer being sequentially stacked away from the base substrate, and an orthographic projection of the fourth conductive layer on the base substrate being overlapped with the orthographic projection of each of the at least part of the second signal lines on the base substrate.

10. (canceled)

11. The display substrate of claim 4, wherein the first signal line further comprises a fourth conductive layer and a fifth conductive layer located on a side of the first conductive layer and the second conductive layer close to the base substrate, and a third conductive layer and a sixth conductive layer located on a side of the first conductive layer and the second conductive layer away from the base substrate, and wherein
the fifth conductive layer, the fourth conductive layer, the first conductive layer, the second conductive layer, the third conductive layer, and the sixth conductive layer are sequentially stacked away from the base substrate,
the first conductive layer, the second conductive layer, the third conductive layer, the fourth conductive layer, the fifth conductive layer, and the sixth conductive layer are electrically connected together, the at least part of the second signal lines are located in the same layer as the fourth conductive layer, and orthographic projections of the fifth conductive layer and the sixth conductive layer on the base substrate are each overlapped with the orthographic projection of each of the at least part of the second signal lines on the base substrate.

12. The display substrate of claim 11, further comprising: a first connection electrode, a second connection electrode, and at least one touch electrode layer located on a side of the pixel circuits away from the base substrate; and a shielding layer located on a side of the pixel circuits close to the base substrate, wherein
each pixel circuit comprises at least one thin film transistor, each thin film transistor comprising an active layer located on a side of the base substrate, a gate electrode located on a side of the active layer away from the base substrate, and a source electrode and a drain electrode located on a side of the gate electrode away from the base substrate;
an orthographic projection of the shielding layer on the base substrate is overlapped with an orthographic projection of the active layer on the base substrate;
the first connection electrode is located on a side of the thin film transistor away from the base substrate, and is electrically connected with the thin film transistor;
the second connection electrode is located on a side of the first connection electrode away from the base substrate, and is electrically connected with the first connection electrode;
the light-emitting element is located on a side of the second connection electrode away from the base substrate, and is electrically connected with the second connection electrode;
the at least one touch electrode layer is located on a side of the light-emitting element away from the base substrate;
the first conductive layer and the first connection electrode are located in a same layer;
the second conductive layer and the second connection electrode are located in a same layer;
the third conductive layer and the first electrode are located in a same layer;
the fourth conductive layer is located in the same layer as the source electrode and the drain electrode;
the fifth conductive layer and the shielding layer are located in a same layer; and
the sixth conductive layer and any one of the at least one touch electrode layer are located in a same layer.

13. The display substrate of claim 1, wherein the bezel area comprises a first bezel area, a second bezel area, a third bezel area, and a fourth bezel area sequentially disposed around the display area, the functional element is located in the display area, and the functional element is disposed close to the first bezel area,
the functional part is respectively connected with the second signal lines through signal leads, and the signal leads extend from the functional element to the first bezel area and are connected with the second signal lines in the first bezel area;
the display substrate further comprises signal input pads located in the third bezel area, wherein
the plurality of second signal lines extend from the first bezel area to the third bezel area through the second bezel area and are connected with the signal input pads.

14. The display substrate of claim 1, wherein the first signal line is located in at least the first bezel area, the second bezel area, and the fourth bezel area, and the orthographic projection of each of the at least part of the second signal lines on the base substrate is overlapped with an orthographic projection of a part of the first signal line in the second bezel area on the base substrate.

15. A display substrate, comprising a display area and a bezel area, the bezel area at least partially surrounding the display area, and the display substrate comprises a base substrate, a plurality of pixel units, a functional element, a first signal line and a second signal line, wherein
the pixel units, the functional element, the first signal line and the second signal line are respectively located on a side of the base substrate;
the pixel unit comprises a pixel circuit and a light-emitting element, the light-emitting element being located on a side of the pixel circuit away from the base substrate, and the pixel circuit being electrically connected with the light-emitting element;
the pixel unit and the functional element are located in the display area, and the pixel unit at least partially surrounds the functional element;
the first signal line and the second signal line are located in the bezel area;
the first signal line is electrically connected with the pixel unit, and the second signal line is electrically connected with the functional element;
the first signal line comprises at least two conductive layers, the at least two conductive layers are located in different layers, an insulating layer is arranged between any two adjacent ones of the at least two conductive layers, and any two adjacent ones of the at least two conductive layers are connected with each other through a via hole formed in the insulating layer; and
the second signal line and one of the at least two conductive layers are located in a same layer, and an orthographic projection of the second signal line on the base substrate is overlapped with an orthographic projection of at least one of the at least two conductive layers on the base substrate.

16. The display substrate of claim 15, wherein the first signal line comprises at least three conductive layers, every two adjacent ones of the at least three conductive layers form a group, the at least three conductive layers comprise at least two groups, and
the orthographic projection of the second signal line on the base substrate is overlapped with the orthographic projection of a connection via hole between two adjacent conductive layers of each of at least one group in at least two groups on the base substrate.

17. The display substrate of claim 16, wherein at least two conductive layers of the at least three conductive layers are located on a side of the second signal line away from the base substrate, and any two adjacent ones of the at least two conductive layers are connected with each other through a first via hole formed in the insulating layer; and the orthographic projection of the second signal line on the base substrate is located within an orthographic projection of the first via hole on the base substrate,
a conductive layer located in the same layer as the second signal line is connected with a conductive layer adjacent to the second signal line and located on the side of the second signal line away from the base substrate through a second via hole formed in the insulating layer, and an orthographic projection of the second via hole on the base substrate is located within the orthographic projection of the first via hole on the base substrate, and
at least one of the at least three conductive layers is located on a side of the second signal line close to the base substrate, the conductive layer in the same layer as the second signal line is connected with the conductive layer which is located on the side of the second signal line close to the base substrate and is adjacent to the second signal line through a third via hole formed in the insulating layer, and an orthographic projection of the third via hole on the base substrate is located within the orthographic projection of the first via hole on the base substrate.

18-19. (canceled)

20. The display substrate of claim 17, wherein a plurality of second signal lines are provided, and the plurality of second signal lines are distributed at intervals;
a total distribution width of orthographic projections of the second signal lines on the base substrate is larger than a width of the orthographic projection of the second via hole on the base substrate, and
the total distribution width of the orthographic projections of the second signal lines on the base substrate is larger than a width of the orthographic projection of the third via hole on the base substrate.

21. The display substrate of claim 16, wherein at least two conductive layers of the at least three conductive layers are located on a side of the second signal line close to the base substrate, and any two adjacent ones of the at least two conductive layers are connected together through a fourth via hole formed in the insulating layer; and the orthographic projection of the second signal line on the base substrate is overlapped with an orthographic projection of the fourth via hole on the base substrate;
at least one of the at least three conductive layers is located on a side of the second signal line away from the base substrate, and the orthographic projections of the fourth via hole and the second signal line on the base substrate are located within an orthographic projection of the conductive layer located on the side of the second signal line away from the base substrate side on the base substrate; and
the conductive layer located in the same layer as the second signal line is connected with the conductive layer located on the side of the second signal line close to the base substrate and adjacent to the second signal line through a fifth via hole formed in the insulating layer, the conductive layer in the same layer as the second signal line is connected with the conductive layer located on the side of the second signal line away from the base substrate and adjacent to the second signal line through a sixth via hole formed in the insulating layer, and orthographic projections of the fifth via hole and the sixth via hole on the base substrate coincide.

22-23. (canceled)

24. The display substrate of claim 21, wherein a plurality of second signal lines are provided, and the plurality of second signal lines are arranged at intervals;
a total distribution width of orthographic projections of the second signal lines on the base substrate is larger than a width of the orthographic projection of the fifth via hole on the base substrate.

25. The display substrate of claim 16, wherein the orthographic projection of the second signal line on the base substrate is not overlapped with an orthographic projection of a connection via hole connecting any two adjacent ones of the at least three conductive layers on the base substrate.

26. The display substrate of claim 25, wherein a plurality of second signal lines are provided, and the plurality of second signal lines are arranged at intervals;
a total distribution width of orthographic projections of the second signal lines on the base substrate is larger than a width of an orthographic projection of the connection via hole connecting any two adjacent ones of the at least three conductive layers on the base substrate.

27. The display substrate of claim 16, wherein at least one of the at least three conductive layers is located on a side of the second signal line away from the base substrate, and at least one of the at least three conductive layers is located on a side of the second signal line close to the base substrate.

28. A display panel, comprising the display substrate of claim 1.
